(19) United States
(12) Patent Application Publication
(10) Pub. No.: US 2005/0174139 A1
(43) Pub. Date: Aug. 11, 2005

(54) Apparatus for high speed probing of flat panel displays

(76) Inventors: Mahendran Chidambaram, Saratoga, CA (US); Lalo Ruiz Vayardo, Gilroy, CA (US)

Correspondence Address: Mahendran Chidambaram, 14058 ABDULLA WAY, SARATOGA, CA, 95070, US

(21) Appl. No.: 10/964,120

(22) Filed: Oct. 13, 2004

Related U.S. Application Data
(60) Provisional application No. 60/510,427, filed on Oct. 14, 2003.

(51) Int. Cl. G01R 31/00

(52) U.S. Cl. 324/770

(57) ABSTRACT

The invention includes an apparatus for high speed probing of flat panel displays. In this invention the above said system apparatus consists of a frame, a precision dual gantry mechanism which houses two Z translation devices, a vision unit, two rotary direct drive mechanisms for positioning and two probe cards. A substrate holding device holds the display under test. In brief the system works as follows to achieve the function of high speed probing. A large substrate to be electrically tested is placed on the fixed substrate holding device and held down with vacuum. A dual gantry system which houses the Z translation devices holds two probing devices. The gantry's are independently controlled and are brought in close proximity to the display under test so the pins can make accurate contact to several bond pads located in both horizontal and vertical directions. Testing is then conducted by passing electrical signals from the tester mounted in close proximity to the display under test. Testing is then repeated for different displays located on the substrate at a very high speed using the dual gantry stages.

### CROSS-REFERENCE TO RELATED APPLICATIONS

The present application claims priority under 35 U.S.C. § 119(e) to U.S. provisional patent application entitled “Apparatus for high speed probing of flat panel displays” filed on Oct. 13, 2003, having Ser. No. 60/510,427, which is incorporated by reference in its entirety.

### BACKGROUND OF THE INVENTION

Field of the Invention

The present invention relates to an apparatus for high speed probing of substrates such as flat panel displays.

### SUMMARY OF THE INVENTION

The general purpose of the present invention, which will be described subsequently in greater detail, is to provide a new apparatus for high speed probing of flat panel displays. The goal is to improve the overall throughput of the machine and in turn reduce cost of testing.

The invention has many advantages and many novel features that result in a new and accurate apparatus for electrical contact testing of substrates which is not anticipated, rendered obvious, suggested, or even implied.

This invention describes,
a. An innovative dual gantry apparatus for high speed probing of substrates such as flat panel displays.
b. Two precise x-y translation device using linear motors and air bearing stages for holding and moving two Z translation devices.
c. An apparatus to hold down substrates under test through vacuum grooves with access to vacuum ports located on the bottom surface of the automated chuck.
d. An on-board tester which provides electrical signals through the test interface unit to test functionality and locate defects inherent in substrates.

The present invention generally comprises an innovative dual gantry apparatus to probe large flat panel displays via contacts provided through probe card pins. Through this invention a novel, new and economical way to test large substrates accurately is presented.

When compared to conventional probing schemes for probing large substrates with several contact pads located in horizontal and vertical rows with varying pitch. It is very difficult and cost ineffective to incorporate a large probing device with several pins to make contact to the vertical and horizontal rows of display device simultaneously and still maintain positioning accuracy. Problems such as pin alignment and planarity will affect overall accuracy. Furthermore, when the substrate size changes based on requirements a new probing device needs to be designed to accommodate the corresponding substrate size the above said problems will be enhanced.

The outline below, will broadly describe the important features of the invention in order that the detailed description may be better understood, and in order that the present contribution to the art may be better appreciated. The additional features as illustrated earlier will also be described.

In this respect, before explaining one embodiment of the invention in detail, it should be understood that the invention by itself is not limited to the current application. The invention is capable of being practiced and carried out in various ways. Also it should be understood that the terminology employed are for the purpose of description and not regarded as limiting.

The primary function of the invention is to provide an apparatus for high speed probing of substrates such as flat panel displays.

Another feature is to provide a method and apparatus to accurately micro step within the same panel when panel sizes exceed sizes of 20″ and above.

Another feature of the present invention is to illustrate a new method for accurate high speed probing and testing of substrates using a dual gantry apparatus.

Finally other features of the present invention will become obvious to the reader and it is intended that these features be within the scope of the present invention.

For accomplishing the above said functionality and features, this invention may be embodied in the form illustrated in the accompanying drawings. However it should be understood that the drawings are for illustrative purpose only and may be subject to change.

### BRIEF DESCRIPTION OF THE DRAWINGS

Various other features and advantages of the present invention will become more apparent as the invention becomes better understood when considered in conjunction with the accompanying drawings, in which through reference designators the different parts of the system will be clearly indicated.

FIG. 1 shows a detailed close up view of the dual gantry apparatus.

FIG. 2 shows the technique of Micro stepping within the same panel.

FIG. 3 shows the side view of the system with pointers to critical features necessary to achieve the above stated function of high speed probing and testing of flat panel displays

### DETAILED DESCRIPTION OF THE INVENTION

Turning now descriptively to the drawings, in which the all the figures comprehensively illustrate a complete method and apparatus to electrically probe a flat panel display using a dual gantry apparatus.

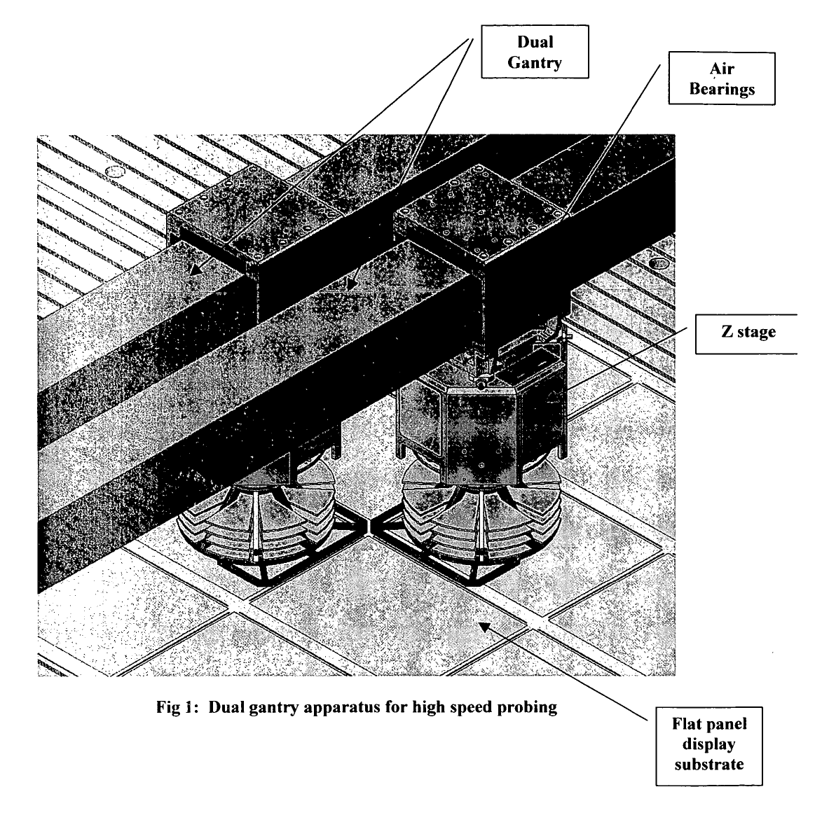

FIG. 1 illustrates a dual gantry apparatus. The dual gantry apparatus consists of two rectangular lightweight beams carrying two Z translation devices. The stages rotate and move at high speeds within the beam they are adhered to through linear motors and air bearing stages.

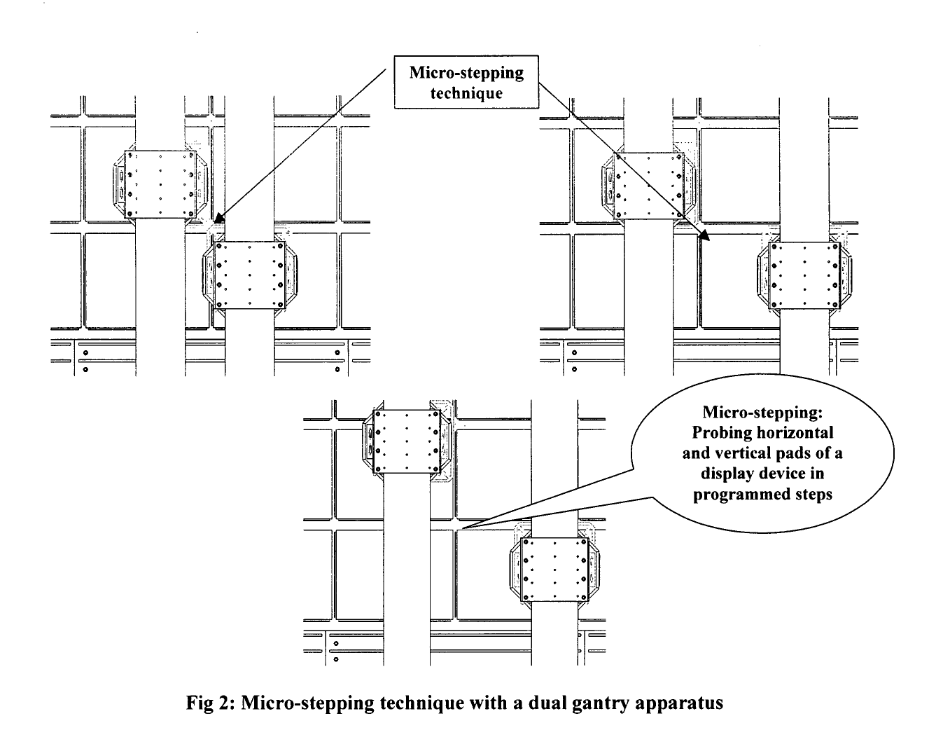

FIG. 2 shows the technique of micro-stepping which is an important feature of the dual gantry system. The micro stepping technique allows the individual stages and beams to move independently for repeated touchdowns on large panels. The key advantage by performing such an operation is to be able to probe large panels such as LCD television substrates using standard off the shelf probing interfaces (probe card).

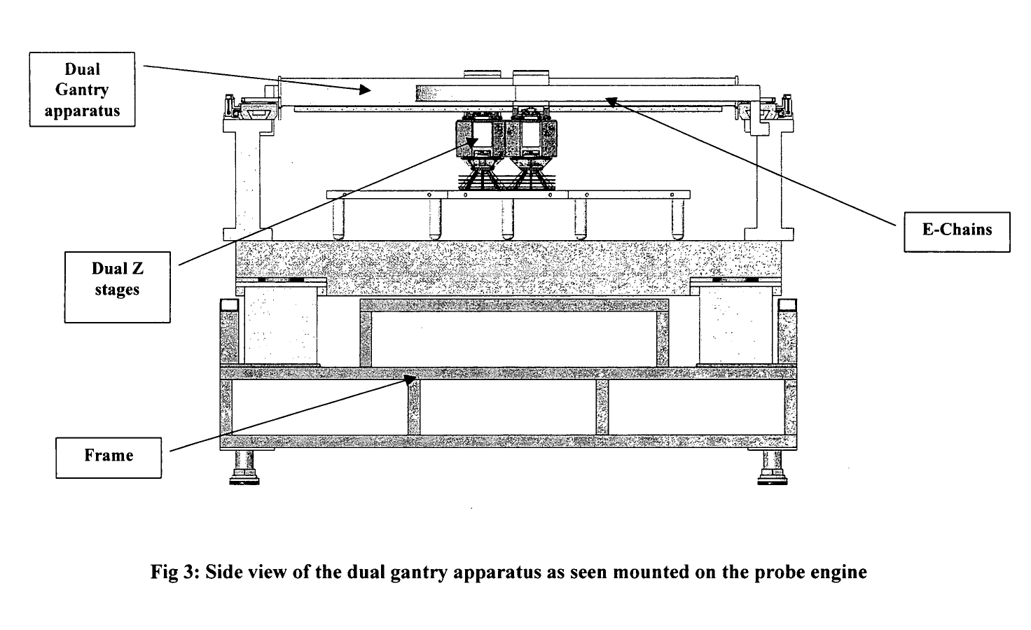

FIG. 3 primarily shows the side of the gantry system with pointers to the conceptual dual gantry apparatus along with a probe card with a plurality of measurement pins otherwise known as probe pins used to make contact with the bond pad of the substrate under test.

As to a further discussion of the manner of usage and operation of the present invention, the same should be apparent from above description. Hence, no further discussion relating to the manner of usage and operation will be provided.

With respect to the above description it is to be realized that the optimum relationships for the parts of the invention, to include variations in software, systems, shape, form, function and manner of operation, assembly and use, are deemed readily apparent and obvious to one skilled in the art, and all equivalent relationships to those illustrated in the drawings and described in the specification are intended to be encompassed by the present invention. Therefore, the foregoing is considered as illustrative only of the principles of the invention. Further since numerous modifications and changes will readily occur to those skilled in the art, it is not desired to limit the invention to the exact construction and operation shown and described, and accordingly, all suitable modifications and equivalents may be resorted to, falling within the scope of the invention.

1. A apparatus for high speed probing of flat panel displays comprising of:
A dual gantry apparatus which comprises of two moving configurable test head assemblies with probing devices to make contact with the display under test on equally spaced contact pads located on the display. Electrical signals are then applied to the flat panel display under test through the probing devices.

2. The high speed probing apparatus according to claim 1 wherein the dual gantry apparatus probes the display using:
e. A Micro-stepping technique in both the horizontal and vertical equally spaced contact pads of a flat panel display in programmed steps.
f. A precise x-y translation assembly using linear motors and air bearing stages for holding and moving the test heads.
g. A method wherein the said flat panel display is probed in portions to facilitate high speed testing.
h. An apparatus which facilitates the addition of 2, 4, or 6 configurable test heads to perform very high speed probing of flat panel displays.
